(19) United States
(12) Patent Application Publication
(10) Pub. No.: US 2023/0021668 A1
(43) Pub. Date: Jan. 26, 2023

(54) TEMPERATURE CONTROL METHOD, MEMORY STORAGE APPARATUS, AND MEMORY CONTROL CIRCUIT UNIT

(71) Applicant: PHISON ELECTRONICS CORP., Miaoli (TW)

(72) Inventors: Yu-Hung Yeh, Taipei City (TW); Yun-You Lin, Kaohsiung City (TW)

(73) Assignee: PHISON ELECTRONICS CORP., Miaoli (TW)

(21) Appl. No.: 17/396,770

(22) Filed: Aug. 9, 2021

(30) Foreign Application Priority Data
Jul. 23, 2021 (TW) 110127180

(51) Int. Cl. G11C 7/04; G11C 16/34; G06F 1/20; G06F 1/3234; G06F 9/50

(52) U.S. Cl. CPC G11C 7/04; G11C 16/3495; G06F 1/206; G06F 1/3275; G06F 9/5094

(57) ABSTRACT

A temperature control method, a memory storage apparatus, and a memory control circuit unit are disclosed. The method includes: detecting a system parameter of the memory storage apparatus, and the system parameter reflects wear of a rewritable non-volatile memory module in the memory storage apparatus; determining a temperature control threshold value according to the system parameter; and performing a temperature reducing operation in response to a temperature of the memory storage apparatus reaching the temperature control threshold value to reduce the temperature of the memory storage apparatus.

### CROSS-REFERENCE TO RELATED APPLICATION

This application claims the priority benefit of Taiwan application serial no. 110127180, filed on Jul. 23, 2021. The entirety of the above-mentioned patent application is hereby incorporated by reference herein and made a part of this specification.

### BACKGROUND OF THE INVENTION

### Field of the Invention

The invention relates to a temperature control technique, and particularly relates to a temperature control method, a memory storage apparatus, and a memory control circuit unit.

### Description of Related Art

Portable electronic apparatuses such as mobile phones and notebook computers have grown rapidly in the past few years, which has led to a rapid increase in consumer demand for storage media. Since a rewritable non-volatile memory module (such as a flash memory) has characteristics such as data non-volatility, power-saving, small size, and no mechanical structures, the rewritable non-volatile memory module is very suitable to be built into the various portable electronic apparatuses provided above.

The rewritable non-volatile memory module has very high requirements for temperature control. If the temperature of the rewritable non-volatile memory module is too high, the reliability of the data stored in the rewritable non-volatile memory module may be significantly affected. However, if a temperature control threshold value that is too strict is used to control the time point of the temperature reducing operation, unnecessary restrictions may occur to the operation of the rewritable non-volatile memory module that is currently still in a healthy state.

### SUMMARY OF THE INVENTION

The invention provides a temperature control method, a memory storage apparatus, and a memory control circuit unit that may achieve a better balance between the working performance of the memory storage apparatus and the temperature control mechanism according to the wear (or health status) of the rewritable non-volatile memory module.

An exemplary embodiment of the invention provides a temperature control method used in a memory storage apparatus. The memory storage apparatus includes a rewritable non-volatile memory module. The temperature control method includes: detecting a system parameter of the memory storage apparatus, wherein the system parameter reflects wear of the rewritable non-volatile memory module; determining a temperature control threshold value according to the system parameter; and performing a temperature reducing operation in response to a temperature of the memory storage apparatus reaching the temperature control threshold value to reduce the temperature of the memory storage apparatus.

An exemplary embodiment of the invention further provides a memory storage apparatus including a connection interface unit, a rewritable non-volatile memory module, and a memory control circuit unit. The connection interface unit is configured to be coupled to a host system. The memory control circuit unit is coupled to the connection interface unit and the rewritable non-volatile memory module. The memory control circuit unit is configured to detect a system parameter of the memory storage apparatus. The system parameter reflects wear of the rewritable non-volatile memory module. The memory control circuit unit is further configured to determine a temperature control threshold value according to the system parameter. The memory control circuit unit is further configured to perform a temperature reducing operation in response to a temperature of the memory storage apparatus reaching the temperature control threshold value to reduce the temperature of the memory storage apparatus.

An exemplary embodiment of the invention further provides a memory control circuit unit configured to control a rewritable non-volatile memory module. The memory control circuit unit includes a host interface, a memory interface, and a memory management circuit. The host interface is configured to be coupled to a host system. The memory interface is configured to be coupled to the rewritable non-volatile memory module. The memory management circuit is coupled to the host interface and the memory interface. The memory management circuit is configured to detect a system parameter of the memory storage apparatus. The system parameter reflects wear of the rewritable non-volatile memory module. The memory management circuit is further configured to determine a temperature control threshold value according to the system parameter. The memory management circuit is further configured to perform a temperature reducing operation in response to a temperature of the memory storage apparatus reaching the temperature control threshold value to reduce the temperature of the memory storage apparatus.

An exemplary embodiment of the invention further provides a memory storage apparatus including a connection interface unit, a rewritable non-volatile memory module, and a memory control circuit unit. The connection interface unit is configured to be coupled to a host system. The memory control circuit unit is coupled to the connection interface unit and the rewritable non-volatile memory module. The memory control circuit unit is configured to detect wear of the rewritable non-volatile memory module. The memory control circuit unit is further configured to control a temperature of the memory storage apparatus using a first temperature control mechanism in response to the wear falling within a first wear range. The memory control circuit unit is further configured to control the temperature of the memory storage apparatus using a second temperature control mechanism in response to the wear falling within a second wear range. The first wear range is different from the second wear range, and the first temperature control mechanism is different from the second temperature control mechanism.

Based on the above, after the system parameter in the memory storage apparatus reflecting the wear of the rewritable non-volatile memory module is detected, the temperature control threshold value may be determined according to the system parameter. Thereafter, in response to the temperature of the memory storage apparatus reaching the temperature control threshold value, a temperature reducing operation may be performed to reduce the temperature of the memory storage apparatus. In this way, a better balance may be achieved between the working performance of the memory storage apparatus and the temperature control mechanism.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic diagram illustrating a host system, a memory storage apparatus, and an input/output (I/O) apparatus according to an exemplary embodiment of the invention.

FIG. 2 is a schematic diagram illustrating a host system, a memory storage apparatus, and an I/O apparatus according to an exemplary embodiment of the invention.

FIG. 3 is a schematic diagram illustrating a host system and a memory storage apparatus according to an exemplary embodiment of the invention.

FIG. 4 is a schematic block diagram illustrating a memory storage apparatus according to an exemplary embodiment of the invention.

FIG. 5 is a schematic block diagram illustrating a memory control circuit unit according to an exemplary embodiment of the invention.

FIG. 6 is a schematic diagram illustrating the management of a rewritable non-volatile memory module according to an exemplary embodiment of the invention.

FIG. 7 is a schematic diagram illustrating triggering a temperature reducing operation using a single temperature control threshold value according to an exemplary embodiment of the invention.

FIG. 8 is a schematic diagram illustrating triggering a temperature reducing operation using a plurality of temperature control threshold values according to an exemplary embodiment of the invention.

FIG. 9 is a schematic diagram illustrating adjusting a temperature control threshold value corresponding to wear of a rewritable non-volatile memory module according to an exemplary embodiment of the invention.

FIG. 10 is a flowchart of a temperature control method according to an exemplary embodiment of the invention.

FIG. 11 is a flowchart of a temperature control method according to an exemplary embodiment of the invention.

### DESCRIPTION OF THE EMBODIMENTS

A memory storage apparatus (also referred to as a memory storage system) typically includes a rewritable non-volatile memory module and a controller (also referred to as a control circuit unit). The memory storage apparatus is usually used together with a host system, such that the host system is able to write data into or read data from the memory storage apparatus.

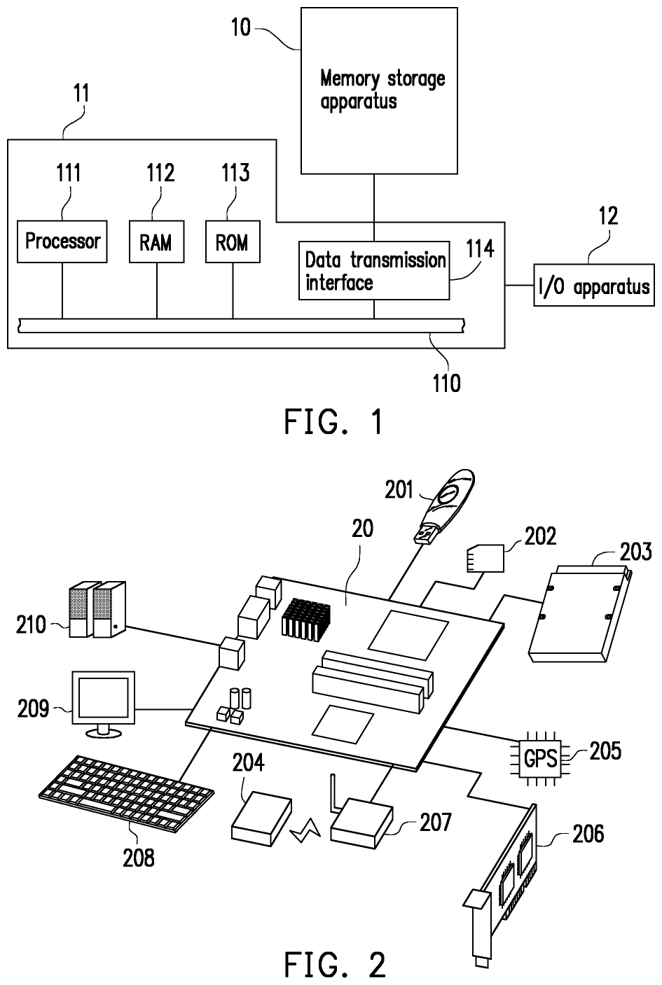

FIG. 1 is a schematic diagram illustrating a host system, a memory storage apparatus, and an input/output (I/O) apparatus according to an exemplary embodiment. FIG. 2 is a schematic diagram illustrating a host system, a memory storage apparatus, and an I/O apparatus according to another exemplary embodiment.

With reference to FIG. 1 and FIG. 2, the host system 11 generally includes a processor 111, a random-access memory (RAM) 112, a read only memory (ROM) 113, and a data transmission interface 114. The processor 111, the RAM 112, the ROM 113, and the data transmission interface 114 are coupled to a system bus 110.

In an exemplary embodiment, the host system 11 is coupled to the memory storage apparatus 10 through the data transmission interface 114. For instance, the host system 11 writes data into the memory storage apparatus 10 or read data from the memory storage apparatus 10 through the data transmission interface 114. The host system 11 is coupled to the I/O apparatus 12 through the system bus 110. For instance, the host system 11 transmits an output signal to the I/O apparatus 12 or receives an output signal from the I/O apparatus 12 through the system bus 110.

In the present exemplary embodiment, the processor 111, the RAM 112, the ROM 113, and the data transmission interface 114 are configured on a motherboard 20 of the host system 11. The number of the data transmission interface 114 may be one or plural. The motherboard 20 is coupled to the memory storage apparatus 10 in a wireless manner or via a cable through the data transmission interface 114.

In an exemplary embodiment, the memory storage apparatus 10 is, for instance, a flash drive 201, a memory card 202, a solid-state drive (SSD) 203 or a wireless memory storage apparatus 204. The wireless memory storage apparatus 204 may be a memory storage apparatus employing various wireless communication techniques, such as a near-field communication (NFC) memory storage apparatus, a wireless fidelity (Wi-Fi) memory storage apparatus, a Bluetooth memory storage apparatus, a Bluetooth memory storage apparatus (e.g., an iBeacon) with low power consumption, and so on. The motherboard 20 may also be coupled to a variety of I/O apparatuses, such as a global positioning system (GPS) module 205, a network interface card 206, a wireless transmission apparatus 207, a keyboard 208, a screen 209, and a speaker 210 through the system bus 110. For instance, in an exemplary embodiment, the motherboard 20 may access the wireless memory storage apparatus 204 through the wireless transmission apparatus 207.

In an exemplary embodiment, the host system 11 is a computer system. In an exemplary embodiment, the host system 11 may be any system that may substantially store data with the memory storage apparatus.

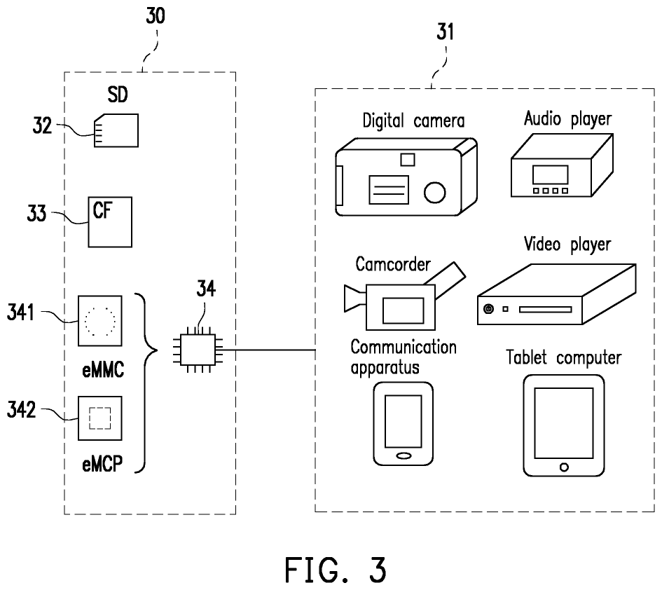

FIG. 3 is a schematic diagram illustrating a host system and a memory storage apparatus according to another exemplary embodiment the invention. With reference to FIG. 3, in another exemplary embodiment, a host system 31 may also be a digital camera, a camcorder, a communication apparatus, an audio player, a video player, a tablet computer, and so on, while a memory storage apparatus 30 used by the host system 31 may be a non-volatile memory apparatus, such as an secure digital (SD) card 32, a compact flash (CF) card 33, and an embedded storage apparatus 34. The embedded storage apparatus 34 includes an embedded multimedia card (eMMC) 341 and/or an embedded multi-chip package (eMCP) storage apparatus 342, wherein a memory module is directly coupled to a substrate of the host system.

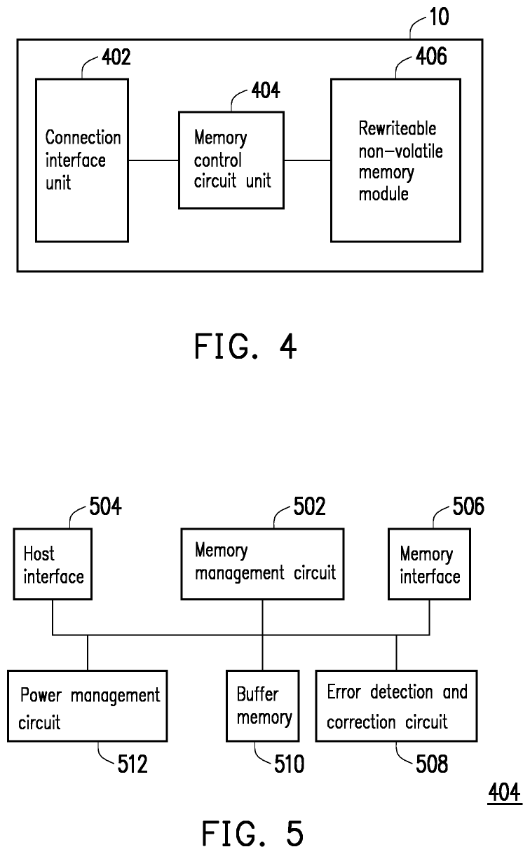

FIG. 4 is a schematic block diagram of a memory storage apparatus according to an exemplary embodiment of the invention. Referring to FIG. 4, the memory storage apparatus 10 includes a connection interface unit 402, a memory control circuit unit 404, and a rewritable non-volatile memory module 406.

The connection interface unit 402 is configured to couple the memory storage apparatus 10 to the host system 11. The memory storage apparatus 10 may communicate with the host system 11 via the connection interface unit 402. In an exemplary embodiment, the connection interface unit 402 is compatible with the Peripheral Component Interconnect Express (PCI Express) standard. In an exemplary embodiment, the connection interface unit 402 may also be compatible with the Serial Advanced Technology Attachment (SATA) standard, Parallel Advanced Technology Attachment (PATA) standard, Institute of Electrical and Electronic Engineers (IEEE) 1394 standard, Universal Serial Bus (USB) standard, SD interface standard, Ultra High Speed-I (UHS-I) interface standard, Ultra High Speed-II (UHS-II) interface standard, Memory Stick (MS) interface standard, MCP interface standard, MMC interface standard, eMMC interface standard, Universal Flash Storage (UFS) interface standard, eMCP interface standard, CF interface standard, Integrated Device Electronics (IDE) standard, or other suitable standards. The connection interface unit 402 may be sealed in one chip with the memory control circuit unit 404. Alternatively, the connection interface unit 402 is disposed outside of a chip containing the memory control circuit unit 404.

The memory control circuit unit 404 is coupled to the connection interface unit 402 and the rewritable non-volatile memory module 406. The memory control circuit unit 404 is configured to execute a plurality of logic gates or control commands implemented in a hardware form or in a firmware form. The memory control circuit unit 404 also performs operations such as writing, reading, and erasing data in the rewritable non-volatile memory storage module 406 according to the commands of the host system 11.

The rewritable non-volatile memory module 406 is configured to store the data written by the host system 11. The rewritable non-volatile memory module 406 may include a single-level cell (SLC) NAND-type flash memory module (that is, a flash memory module that may store 1 bit in one memory cell), a multi-level cell (MLC) NAND-type flash memory module (that is, a flash memory module that may store 2 bits in one memory cell), a triple-level cell (TLC) NAND-type flash memory module (i.e., a flash memory module that may store 3 bits in one memory cell), a quad-level cell (QLC) NAND-type flash memory module (that is, a flash memory module that may store 4 bits in one memory cell), other flash memory modules, or other memory modules with the same characteristics.

Each of the memory cells in the rewritable non-volatile memory module 406 stores one or a plurality of bits via the change in voltage (also referred to as threshold voltage hereinafter). Specifically, a charge trapping layer is disposed between the control gate and the channel of each of the memory cells. By applying a write voltage to the control gate, the number of electrons of the charge-trapping layer may be changed, and therefore the threshold voltage of the memory cells may be changed. This operation of changing the threshold voltage of the memory cells is also referred to as “writing data to the memory cells” or “programming the memory cells”. As the threshold voltage is changed, each of the memory cells in the rewritable non-volatile memory module 406 has a plurality of storage statuses. Which storage status one memory cell belongs to may be determined via the application of a read voltage, so as to obtain one or a plurality of bits stored by the memory cell.

In an exemplary embodiment, the memory cells of the rewritable non-volatile memory module 406 may form a plurality of physical programming units, and these physical programming units may form a plurality of physical erasing units. Specifically, the memory cells on the same word line may form one or a plurality of physical programming units. If each memory cell may store two or more bits, then the physical programming units on the same word line may at least be classified into lower physical programming units and upper physical programming units. For example, the least significant bit (LSB) of a memory cell belongs to the lower physical programming unit, and the most significant bit (MSB) of a memory cell belongs to the upper physical programming unit. Generally, in an MLC NAND-type flash memory, the write speed of the lower physical programming unit is greater than the write speed of the upper physical programming unit, and/or the reliability of the lower physical programming unit is greater than the reliability of the upper physical programming unit.

In an exemplary embodiment, the physical programming unit is the smallest unit of programming. That is, the physical programming unit is the smallest unit of data writing. For example, the physical programming unit may be a physical page or a physical sector. If the physical programming unit is a physical page, then the physical programming unit may include a data bit area and a redundant bit area. The data bit area contains a plurality of physical pages configured to store user data, and the redundant bit area is configured to store system data (for example, management data such as an ECC). In an exemplary embodiment, the data bit area contains 32 physical pages, and the size of one physical sector is 512 bytes (B). However, in other exemplary embodiments, the data bit area may also contain 8, 16, or a greater or lesser number of physical pages, and the size of each of the physical pages may also be greater or smaller. Moreover, the physical erasing unit is the smallest unit of erasing. That is, each of the physical erasing units contains the smallest number of memory cells erased together. For example, the physical erasing unit is a physical block.

FIG. 5 is a schematic block diagram of a memory control circuit unit according to an exemplary embodiment of the invention. Referring to FIG. 5, the memory control circuit unit 404 includes a memory management circuit 502, a host interface 504, a memory interface 506, and an error detection and correction circuit 508.

The memory management circuit 502 is configured to control the overall operation of the memory control circuit unit 404. Specifically, the memory management circuit 502 has a plurality of control commands. During operation of the memory storage apparatus 10, the control commands are executed to perform operations such as writing, reading, and erasing data. In the following, descriptions relating to the operation of the memory management circuit 502 are equivalent to the descriptions of the operation of the memory control circuit unit 404.

In an exemplary embodiment, the control commands of the memory management circuit 502 are implemented in a firmware form. For example, the memory management circuit 502 has a microprocessor unit (not shown) and a read-only memory (not shown), and the control commands are burned into the ROM. During the operation of the memory storage apparatus 10, the control commands are executed by the microprocessor unit to perform operations such as writing, reading, and erasing data.

In an exemplary embodiment, the control commands of the memory management circuit 502 may also be stored in the form of program codes in a specific area (for example, the system area in a memory module exclusively configured to store system data) of the rewritable non-volatile memory module 406. Moreover, the memory management circuit 502 has a microprocessor unit (not shown), a ROM (not shown), and a RAM (not shown). In particular, the ROM has a boot code, and when the memory control circuit unit 404 is enabled, the microprocessor unit first executes the boot code to load the control commands stored in the rewritable non-volatile memory module 406 into the RAM of the memory management circuit 502. Next, the microprocessor unit runs the control commands to perform operations such as writing, reading, and erasing data.

In an exemplary embodiment, the control commands of the memory management circuit 502 may also be implemented in a hardware form. For example, the memory management circuit 502 includes a microcontroller, a memory cell management circuit, a memory write circuit, a memory read circuit, a memory erase circuit, and a data processing circuit. The memory cell management circuit, the memory write circuit, the memory read circuit, the memory erase circuit, and the data processing circuit are coupled to the microcontroller. The memory cell management circuit is configured to manage the memory cells or memory cell groups of the rewritable non-volatile memory module 406. The memory write circuit is configured to issue a write command sequence to the rewritable non-volatile memory module 406 to write data into the rewritable non-volatile memory module 406. The memory read circuit is configured to issue a read command sequence to the rewritable non-volatile memory module 406 to read data from the rewritable non-volatile memory module 406. The memory erase circuit is configured to issue an erase command sequence to the rewritable non-volatile memory module 406 to erase data from the rewritable non-volatile memory module 406. The data processing circuit is configured to process data to be written into the rewritable non-volatile memory module 406 and data read from the rewritable non-volatile memory module 406. The write command sequence, the read command sequence, and the erase command sequence may independently include one or a plurality of program codes or command codes and be configured to instruct the rewritable non-volatile memory module 406 to execute corresponding operations such as writing, reading, and erasing. In an exemplary embodiment, the memory management circuit 502 may also issue other types of command sequences to the rewritable non-volatile memory module 406 to instruct the execution of corresponding operations.

The host interface 504 is coupled to the memory management circuit 502. The memory management circuit 502 may communicate with the host system 11 via the host interface 504. The host interface 504 may be used to receive and identify commands and data sent by the host system 11. For example, the commands and data sent by the host system 11 may be sent to the memory management circuit 502 via the host interface 504. In addition, the memory management circuit 502 may send data to the host system 11 via the host interface 504. In the present exemplary embodiment, the host interface 504 is compatible with the PCI Express standard. However, it should be understood that the invention is not limited thereto, and the host interface 504 may also be compatible with the SATA standard, PATA standard, IEEE 1394 standard, USB standard, SD standard, UHS-I standard, UHS-II standard, MS standard, MMC standard, eMMC standard, UFS standard, CF standard, IDE standard, or other suitable standards for data transmission.

The memory interface 506 is coupled to the memory management circuit 502 and is configured to access the rewritable non-volatile memory module 406. In other words, data to be written into the rewritable non-volatile memory module 406 is converted to a format acceptable to the rewritable non-volatile memory module 406 via the memory interface 506. Specifically, if the memory management circuit 502 is to access the rewritable non-volatile memory module 406, then the memory interface 506 sends a corresponding command sequence. For example, the command sequence may include a write command sequence instructing data writing, a read command sequence instructing data reading, an erase command sequence instructing data erasing, and corresponding command sequences configured to instruct various memory operations (such as changing read voltage level or executing a garbage collection operation). The command sequences are generated by, for example, the memory management circuit 502 and sent to the rewritable non-volatile memory module 406 via the memory interface 506. The command sequences may include one or a plurality of signals or data on a bus. The signals or data may include a command code or a program code. For example, when reading a command sequence, information such as read identification code or memory address is included.

The error detection and correction circuit 508 is coupled to the memory management circuit 502 and configured to execute an error detection and correction operation to ensure the correctness of data. Specifically, when the memory management circuit 502 receives a write command from the host system 11, the error detection and correction circuit 508 generates a corresponding error correction code (ECC) and/or an error detection code (EDC) for data corresponding to the write command, and the memory management circuit 502 writes the data corresponding to the write command and the corresponding ECC and/or EDC into the rewritable non-volatile memory module 406. Next, when reading data from the rewritable non-volatile memory module 406, the memory management circuit 502 reads the ECC and/or the EDC corresponding to the data at the same time, and the error detection and correction circuit 508 executes an error detection and correction operation on the read data based on the ECC and/or the EDC.

In an exemplary embodiment, the memory control circuit unit 404 further includes a buffer memory 510 and a power management circuit 512. The buffer memory 510 is coupled to the memory management circuit 502 and configured to temporarily store data and commands from the host system 11 or data from the rewritable non-volatile memory module 406. The power management circuit 512 is coupled to the memory management circuit 502 and configured to control the power of the memory storage apparatus 10.

In an exemplary embodiment, in FIG. 4, the memory storage apparatus 10 is also referred to as a flash memory storage apparatus, the rewritable non-volatile memory module 406 is also referred to as a flash memory module, and the memory control circuit unit 404 is also referred to as a flash memory controller. In an exemplary embodiment, the memory management circuit 502 of FIG. 5 is also referred to as a flash memory management circuit.

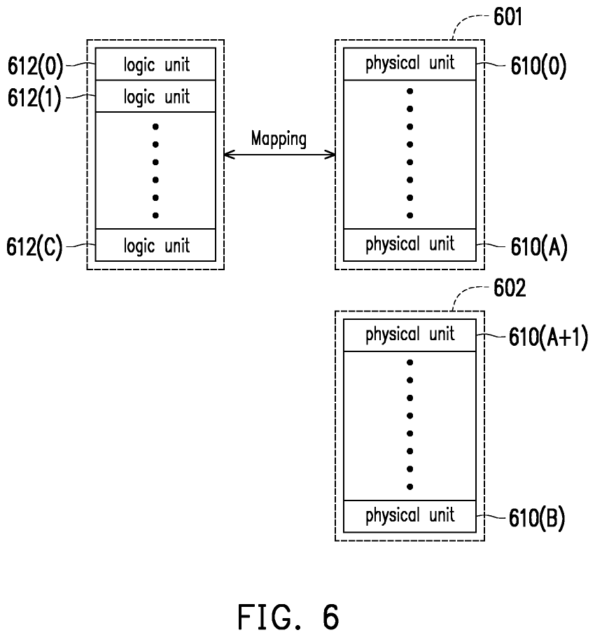

FIG. 6 is a schematic diagram illustrating the management of a rewritable non-volatile memory module according to an exemplary embodiment of the invention. Referring to FIG. 6, the memory management circuit 502 may logically group physical units 610(0) to 610(B) in the rewritable non-volatile memory module 406 into a storage area 601 and a spare area 602. In an exemplary embodiment, one physical unit refers to one physical address or one physical programming unit. In an exemplary embodiment, one physical unit may also be formed by a plurality of continuous or discontinuous physical addresses.

The physical units 610(0) to 610(A) in the storage area 601 are configured to store user data (for example, user data from the host system 11 in FIG. 1). For example, the physical units 610(0) to 610(A) in the storage area 601 may store valid data and invalid data. The physical units 610(A+1) to 610(B) in the spare area 602 do not store data (for example, valid data). For example, if a certain physical unit does not store valid data, then this physical unit may be associated (or added) to the spare area 602. In addition, the physical units in the spare area 602 (or physical units that do not store valid data) may be erased. When writing new data, one physical unit may be extracted from the spare area 602 to store the new data. In an exemplary embodiment, the spare area 602 is also referred to as a free pool.

The memory management circuit 502 may configure logic units 612(0) to 612(C) to map the physical units 610(0) to 610(A) in the storage area 601. In an exemplary embodiment, each of the logic units corresponds to one logical address. For example, one logical address may include one or a plurality of logical block addresses (LBAs) or other logical management units. In an exemplary embodiment, one logic unit may also correspond to one logic programming unit or be formed by a plurality of continuous or discontinuous logical addresses. Moreover, one logic unit may be mapped to one or a plurality of physical units. It should be noted that if a certain physical unit is currently mapped by a certain logic unit, then the data currently stored in this physical unit is valid data. On the other hand, if a certain physical unit is not currently mapped by any logic unit, then the data currently stored in this physical unit is invalid data.

The memory management circuit 502 may record the management data describing the mapping relationship between logic units and physical units (also called logical-to-physical or logical address-to-logical address (L2P) mapping information) in at least one L2P mapping table. When the host system 11 is to read data from the memory storage apparatus 10 or write data to the memory storage apparatus 10, the memory management circuit 502 may execute a data access operation on the memory storage apparatus 10 according to the L2P mapping table.

The memory management circuit 502 may detect a system parameter of the memory storage apparatus 10. The system parameter may reflect the wear of the rewritable non-volatile memory module 406. For example, before the rewritable non-volatile memory module 406 is shipped, the wear of the rewritable non-volatile memory module 406 may be relatively lower and each of the memory cells in the rewritable non-volatile memory module 406 is relatively healthier. After the rewritable non-volatile memory module 406 is shipped, in response to the increase in the use time and/or frequency of the rewritable non-volatile memory module 406, the wear of the rewritable non-volatile memory module 406 may continue to be increased, and the degree of health of each of the memory cells in the rewritable non-volatile memory module 406 is also gradually decreased.

In an exemplary embodiment, the wear of the rewritable non-volatile memory module 406 may be affected by the cycle counts of programming, erasing, and/or reading of at least a portion of the physical units in the rewritable non-volatile memory module 406. For example, in response to the increase in the cycle counts of programming, erasing, and/or reading of at least a portion of the physical units in the rewritable non-volatile memory module 406, the wear of the rewritable non-volatile memory module 406 may be correspondingly increased. Moreover, in response to the increase in the wear of the rewritable non-volatile memory module 406, the reliability of the data stored in the rewritable non-volatile memory module 406 is also decreased. Once the reliability of the data stored in the rewritable non-volatile memory module 406 is decreased, the bit error rate (BER) of the data read from the rewritable non-volatile memory module 406 may also be increased (indicating that the number of error bits contained in the read data is increased).

In an exemplary embodiment, the system parameter may include one or a plurality of count values. The count value may reflect the wear (also referred to as the degree of use) of at least one physical unit in the rewritable non-volatile memory module 406. For example, the count value may include at least one or a combination of a programming count value, an erase count value, a read count value, and a bit error rate. The programming count value may reflect the cycle count that the at least one physical unit is programmed. The erase count value may reflect the cycle count that the at least one physical unit is erased. The read count value may reflect the cycle count that the at least one physical unit is read. The bit error rate may reflect the bit error rate of the at least one physical unit or the data read from the at least one physical unit. It should be noted that, in an exemplary embodiment, the system parameter may also include other types of count values, as long as they may reflect the wear of at least one physical unit in the rewritable non-volatile memory module 406.

In an exemplary embodiment, the memory management circuit 502 may obtain or evaluate the wear of the rewritable non-volatile memory module 406 according to the system parameter. For example, the count value may be positively correlated to the wear of the rewritable non-volatile memory module 406. For example, in response to the increase in the programming count value, the erase count value, the read count value, and/or the bit error rate, the memory management circuit 502 may determine that the wear of the rewritable non-volatile memory module 406 is increased.

In an exemplary embodiment, the memory management circuit 502 may set one or a plurality of wear threshold values. The memory management circuit 502 may determine the wear of the rewritable non-volatile memory module 406 according to the comparison result of the system parameter and the one or plurality of wear threshold values. In an exemplary embodiment, the one or plurality of wear threshold values may define a plurality of wear ranges. The memory management circuit 502 may determine whether a certain system parameter falls within a certain wear range in the plurality of wear ranges. If a certain system parameter falls within a certain wear range of the plurality of wear ranges, then the memory management circuit 502 may determine the wear of the rewritable non-volatile memory module 406 according to the wear range. In an exemplary embodiment, the memory management circuit 502 may adopt a specific temperature control mechanism according to the wear (or the corresponding wear range) of the rewritable non-volatile memory module 406.

In an exemplary embodiment, the memory management circuit 502 may detect the temperature of the memory storage apparatus 10 in real time. For example, the memory management circuit 502 may obtain the temperature of the memory storage apparatus 10 according to the sensing value returned by a temperature sensor (not shown) disposed in the memory storage apparatus 10 and located near the rewritable non-volatile memory module 406. For example, the temperature of the memory storage apparatus 10 may substantially (i.e., accurately or roughly) reflect the temperature of the rewritable non-volatile memory module 406.

In an exemplary embodiment, the memory management circuit 502 may determine one or a plurality of temperature control threshold values according to the system parameter. The memory management circuit 502 may determine whether the temperature of the memory storage apparatus 10 reaches a certain temperature control threshold value. In response to the temperature of the memory storage apparatus 10 reaching a certain temperature control threshold value, the memory management circuit 502 may perform one temperature reducing operation to reduce the temperature of the memory storage apparatus 10. In an exemplary embodiment, in the temperature reducing operation, the memory management circuit 502 may reduce at least one of the number of parallel access channels and the system clock of the rewritable non-volatile memory module 406 in an attempt to reduce the temperature of the memory storage apparatus 10.

In an exemplary embodiment, the memory management circuit 502 may access a plurality of physical units in the rewritable non-volatile memory module 406 in parallel via a plurality of channels (also referred to as memory channels). For example, a plurality of physical units that may be accessed in parallel in the rewritable non-volatile memory module 406 may be dispersed in one or a plurality of memory dies, one or a plurality of memory planes, and/or one or a plurality of chip enable (CE) areas.

In an exemplary embodiment, the number of parallel access channels reflects the total number of channels currently open for parallel access to the rewritable non-volatile memory module 406. The memory management circuit 502 may dynamically determine the number of parallel access channels. The number of parallel access channels may be positively correlated with the efficiency of the memory management circuit 502 accessing the rewritable non-volatile memory module 406. For example, in response to the increase in the number of parallel access channels, the efficiency of the memory management circuit 502 accessing the rewritable non-volatile memory module 406 is also increased. Moreover, by reducing the number of parallel access channels, the memory management circuit 502 may attempt to reduce the temperature of the memory storage apparatus 10.

In an exemplary embodiment, reducing the number of parallel access channels may include reducing the total number of channels performing programming, reading, or erasing simultaneously. Each of the channels is connected to one memory die, one memory plane, and/or one physical unit in one chip enable area. In an exemplary embodiment, by reducing the number of parallel access channels, in the programming operation, the total number of physical units, memory dies, memory planes, and/or chip enable areas that may perform programming simultaneously may be correspondingly reduced. In an exemplary embodiment, by reducing the number of parallel access channels, in the read operation, the total number of physical units, memory dies, memory planes, and/or chip enable area that may perform reading simultaneously may be correspondingly reduced. In an exemplary embodiment, by reducing the number of parallel access channels, in the erase operation, the total number of physical units, memory dies, memory planes, and/or chip enable area that may perform erasing simultaneously may be correspondingly reduced.

In an exemplary embodiment, the memory management circuit 502 and/or the rewritable non-volatile memory module 406 are/is operated according to the system clock. By reducing the system clock, the memory management circuit 502 may also attempt to reduce the temperature of the memory storage apparatus 10. It should be noted that, in an exemplary embodiment, the memory management circuit 502 may also adjust other types of management parameters or perform other types of temperature reducing operations, as long as the temperature of the memory storage apparatus 10 may be reduced.

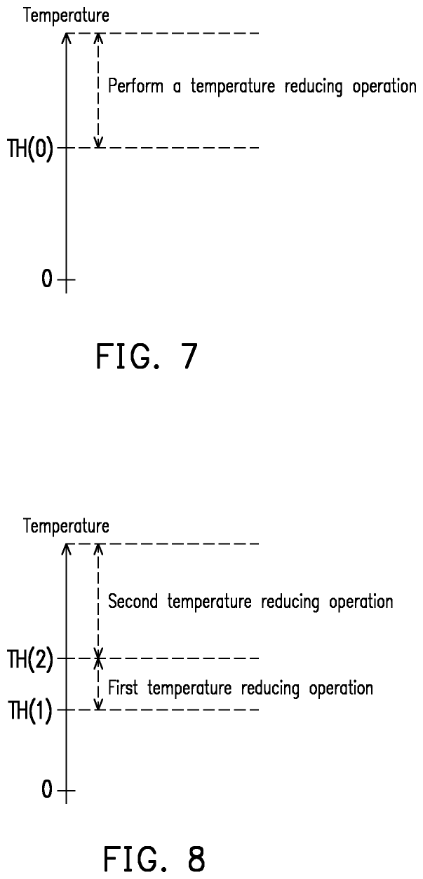

FIG. 7 is a schematic diagram illustrating triggering a temperature reducing operation using a single temperature control threshold value according to an exemplary embodiment of the invention. Please refer to FIG. 7, in an exemplary embodiment, the temperature control threshold value includes a threshold value TH(0). The threshold value TH(0) may be used to trigger one temperature reducing operation. The memory management circuit 502 may determine whether the temperature of the memory storage apparatus 10 reaches (that is, equal to or higher than) the threshold value TH(0). In response to the temperature of the memory storage apparatus 10 reaching the threshold value TH(0), the memory management circuit 502 may perform the temperature reducing operation. The execution details of the temperature reducing operation are described in detail above, and are not repeated herein.

FIG. 8 is a schematic diagram illustrating triggering a temperature reducing operation using a plurality of temperature control threshold values according to an exemplary embodiment of the invention. Referring to FIG. 8, in an exemplary embodiment, the temperature control threshold values include a threshold value (also referred to as a first threshold value) TH(1) and a threshold value (also referred to as a second threshold value) TH(2). The threshold value TH(1) is lower than the threshold value TH(2). The threshold value TH(1) may be used to trigger one temperature reducing operation of the memory storage apparatus 10 (also referred to as a first temperature reducing operation). The threshold value TH(2) may be used to trigger another temperature reducing operation of the memory storage apparatus 10 (also referred to as a second temperature reducing operation).

In an exemplary embodiment, the memory management circuit 502 may determine whether the temperature of the memory storage apparatus 10 reaches (that is, equal to or higher than) the threshold value TH(1). In response to the temperature of the memory storage apparatus 10 reaching the threshold value TH(1) (or between the threshold values TH(1) and TH(2)), the memory management circuit 502 may perform the first temperature reducing operation. Moreover, the memory management circuit 502 may determine whether the temperature of the memory storage apparatus 10 reaches (that is, equal to or higher than) the threshold value TH(2). In response to the temperature of the memory storage apparatus 10 reaching the threshold value TH(2), the memory management circuit 502 may perform the second temperature reducing operation. The temperature reducing means performed in the first temperature reducing operation may be the same as or different from the temperature reducing means performed in the second temperature reducing operation.

It should be mentioned that, the ability or intensity of the second temperature reducing operation to control the temperature drop of the memory storage apparatus 10 is higher than the ability or intensity of the first temperature reducing operation to control the temperature drop of the memory storage apparatus 10. For example, in an exemplary embodiment, the degree of decrease of the number of parallel access channels and/or the system clock of the rewritable non-volatile memory module 406 in the second temperature reducing operation may be higher than the degree of decrease of the number of parallel access channels and/or the system clock of the rewritable non-volatile memory module 406 in the first temperature reducing operation. For example, in the first temperature reducing operation, the number of parallel access channels may be reduced by 10%, and in the second temperature reducing operation, the number of parallel access channels may be reduced by 20%. Therefore, compared to the temperature of the memory storage apparatus 10 being between the threshold values TH(1) and TH(2), when the temperature of the memory storage apparatus 10 is higher than the threshold value TH(2), the temperature of the memory storage apparatus 10 may drop more quickly.

In an exemplary embodiment, the memory management circuit 502 may determine (including setting, adjusting, updating, or changing) the one or plurality of temperature control threshold values according to the current value of the system parameter. For example, in response to a certain system parameter currently being a certain value (also referred to as a first parameter value), the memory management circuit 502 may set a certain temperature control threshold value to a certain value (also referred to as a first value). Thereafter, in response to the system parameter currently being another value (also referred to as a second parameter value), the memory management circuit 502 may set the temperature control threshold value to another specific value (also referred to as a second value). The first parameter value is different from the second parameter value. The first value is different from the second value.

In an exemplary embodiment, in the operation of determining the temperature control threshold value according to the system parameter, the memory management circuit 502 may reduce the temperature control threshold value in response to the increase in the wear of the rewritable non-volatile memory module 406 reflected by the system parameter. The programming count value, the erase count value, the read count value, and/or the bit error rate are examples of the system parameter. In response to the increase in the programming count value, the erase count value, the read count value, and/or the bit error rate (reflecting the increase in the wear of the rewritable non-volatile memory module 406), the memory management circuit 502 may lower the temperature control threshold value.

In an exemplary embodiment, in the case that the number of temperature control threshold values is a plurality, the memory management circuit 502 may individually adjust one of the plurality of temperature control threshold values, or simultaneously adjust at least two of the plurality of temperature control threshold values. Taking FIG. 8 as an example, in response to the system parameter change, at least one of the threshold values TH(1) and TH(2) may be dynamically adjusted (for example, reduced).

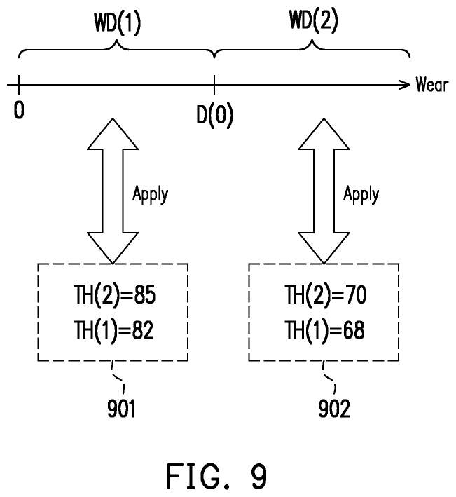

FIG. 9 is a schematic diagram illustrating adjusting the temperature control threshold value corresponding to the wear of the rewritable non-volatile memory module according to an exemplary embodiment of the invention. Referring to FIG. 9, in an exemplary embodiment, in this case, the wear of the rewritable non-volatile memory module 406 is represented by an initial value (for example, a value of 0) when it is just shipped. Thereafter, in response to the increase in the use time and/or use frequency of the rewritable non-volatile memory module 406, the wear of the rewritable non-volatile memory module 406 is also gradually increased.

In an exemplary embodiment, the memory management circuit 502 may detect whether the wear of the rewritable non-volatile memory module 406 falls within a wear range (also known as a first wear range) WD(1) or a wear range (also known as a second wear range) WD(2) according to the system parameter. The wear ranges WD(1) and WD(2) may be demarcated by a wear threshold value D(0). In response to the wear falling within the wear range WD(1) (for example, the wear is lower than the wear threshold value D(0)), the memory management circuit 502 may control the temperature of the memory storage apparatus 10 using a temperature control mechanism (also referred to as a first temperature control mechanism) 901. For example, in the first temperature control mechanism, the memory management circuit 502 may apply the temperature control mechanism 901 to set the threshold values TH(1) and TH(2) of FIG. 8 to 82 degrees Celsius and 85 degrees Celsius, respectively. Moreover, in response to the wear falling within the wear range WD(2) (for example, the wear is higher than the wear threshold value D(0)), the memory management circuit 502 may control the temperature of the memory storage apparatus 10 using another temperature control mechanism (also referred to as a second temperature control mechanism) 902. For example, in the second temperature control mechanism, the memory management circuit 502 may apply the temperature control mechanism 902 to set the threshold values TH(1) and TH(2) of FIG. 8 to 68 degrees Celsius and 70 degrees Celsius, respectively. In the first temperature control mechanism and the second temperature control mechanism, the memory management circuit 502 may determine whether to trigger a specific temperature reducing operation to reduce the temperature of the memory storage apparatus 10 according to the currently set temperature control threshold values (for example, the threshold values TH(1) and TH(2)). The relevant operation details are provided above, and are therefore not repeated herein.

It should be noted that the temperature values corresponding to the temperature control threshold values (for example, the threshold values TH(1) and TH(2)) may all be adjusted according to practical requirements, and the invention is not limited in this regard. In addition, the total number of the temperature control threshold values of FIG. 8 or FIG. 9 may also be more (for example, 3, 4, or 5, etc.) or less (for example, 1). In addition, the temperature control threshold values may also define more different temperature reducing operations, depending on practical requirements, and the invention is not limited in this regard.

In an exemplary embodiment, the memory management circuit 502 may evaluate the wear of the rewritable non-volatile memory module 406 according to the system parameter. For example, the memory management circuit 502 may obtain an evaluation value that may be used to evaluate the wear of the rewritable non-volatile memory module 406 according to the system parameter. The evaluation value may be positively correlated to the wear of the rewritable non-volatile memory module 406.

In an exemplary embodiment, the memory management circuit 502 may obtain the evaluation value according to the programming count value, the erase count value, the read count value, and/or the bit error rate, etc., reflecting the count value of the degree of use of at least one physical unit in the rewritable non-volatile memory module 406. In an exemplary embodiment, the memory management circuit 502 may directly set one of the count values such as the programming count value, the erase count value, the read count value, and the bit error rate as the evaluation value. Or, in an exemplary embodiment, the memory management circuit 502 may perform a logic operation on count values such as the programming count value, the erase count value, the read count value, and/or the bit error rate to obtain the evaluation value.

In an exemplary embodiment, the memory management circuit 502 may compare the evaluation value with the wear threshold value D(0). In response to the evaluation value being less than the wear threshold value D(0), the memory management circuit 502 may determine that the wear of the rewritable non-volatile memory module 406 falls within the wear range WD(1) and apply the temperature control mechanism 901 to control the temperature of the memory storage apparatus 10. Moreover, in response to the evaluation value being greater than the wear threshold value D(0), the memory management circuit 502 may determine that the wear of the rewritable non-volatile memory module 406 falls within the wear range WD(2) and apply the temperature control mechanism 902 to control the temperature of the memory storage apparatus 10.

In other words, at the initial stage of use of the rewritable non-volatile memory module 406 (that is, when the rewritable non-volatile memory module 406 has better health and lower wear), the memory management circuit 502 may adopt the temperature control mechanism 901 (i.e., a normal or preset temperature control mechanism) to control the temperature of the memory storage apparatus 10, and maintain the working performance of the rewritable non-volatile memory module 406 as much as possible before starting the temperature reducing operation. Moreover, after the wear of the rewritable non-volatile memory module 406 is increased to a certain level (for example, increased to over the wear threshold value D(0)), the memory management circuit 502 may adopt the temperature control mechanism 902 to control the temperature of the memory storage apparatus 10 to more quickly start the temperature reducing operation (or even adopt a stronger temperature reducing means) after the temperature of the rewritable non-volatile memory module 406 is increased to reduce the temperature of the memory storage apparatus 10. In an exemplary embodiment, the plurality of wear ranges and the total number of different temperature control mechanisms corresponding to the wear ranges may be more, such as 3, 4, or 5, etc., and the invention is not limited in this regard.

In this way, the working performance of the memory storage apparatus 10 and the temperature control mechanism may be better balanced at any stage in the life cycle of the rewritable non-volatile memory module 406. For example, at the early stage of the life cycle of the rewritable non-volatile memory module 406 (for example, the rewritable non-volatile memory module 406 has a lower programming/erase count value), by adopting a higher temperature threshold value, the time point for performing the temperature reducing operation may be postponed and the working performance of the memory storage apparatus 10 and/or the rewritable non-volatile memory module 406 may be maintained as much as possible. However, in the middle and late stages of the life cycle of the rewritable non-volatile memory module 406 (for example, the rewritable non-volatile memory module 406 has a very high programming/erase count value), a lower temperature threshold value may be adopted to advance the time point of the temperature reducing operation to improve the temperature control efficiency of the rewritable non-volatile memory module 406. Therefore, the reliability of the rewritable non-volatile memory module 406 may be maintained or even improved and/or the service life of the rewritable non-volatile memory module 406 may be prolonged.

In an exemplary embodiment, the one or plurality of temperature control threshold values adopted by the first temperature control mechanism may be preset (e.g., increased) by the memory storage apparatus 10 or the memory management circuit 502 before shipment or at the time of shipment, without having to be set by the memory management circuit 502 itself. However, in an exemplary embodiment, the one or plurality of temperature control threshold values adopted in the first temperature control mechanism may also be set by the memory management circuit 502 (for example, increased) after the memory storage apparatus 10 or the memory management circuit 502 is shipped.

Taking FIG. 9 as an example, in this case, the threshold values TH(1) and TH(2) used by the temperature control mechanism 901 are certain values (also called initial values) when the memory storage apparatus 10 or the memory control circuit unit 404 are shipped. For example, the initial values of the threshold values TH(1) and TH(2) in the temperature control mechanism 901 may be 76 degrees and 79 degrees, respectively, and are not limited thereto. After the memory storage apparatus 10 or the memory control circuit unit 404 is shipped, the memory management circuit 502 may actively adjust the threshold values TH(1) and TH(2) in the temperature control mechanism 901 from the initial value to other values (for example, the first value). For example, the threshold values TH(1) and TH(2) in the temperature control mechanism 901 are increased to 82 degrees and 85 degrees, respectively, and are not limited thereto. Thereafter, as the wear of the rewritable non-volatile memory module 406 is gradually increased, the threshold values TH(1) and TH(2) may be reduced, for example, reduced to 68 degrees and 70 degrees in the temperature control mechanism 902. In addition, each of the temperature control threshold values may be adjusted (for example, increased or decreased) one or more times, and the invention is not limited in this regard.

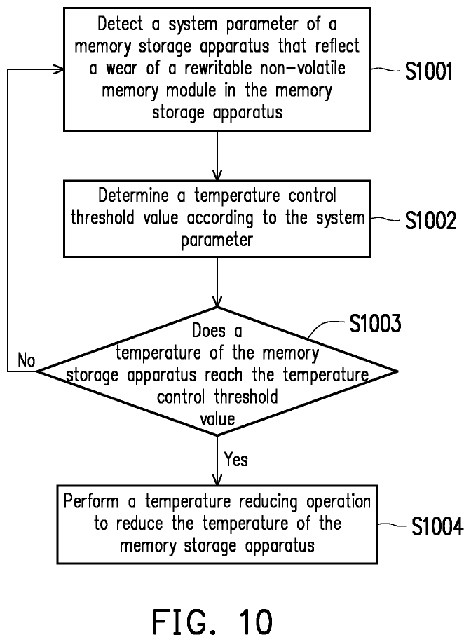

FIG. 10 is a flowchart of a temperature control method according to an exemplary embodiment of the invention. Please refer to FIG. 10, in step S1001, a system parameter of a memory storage apparatus is detected. The system parameter reflects the wear of the rewritable non-volatile memory module in the memory storage apparatus. In step S1002, a temperature control threshold value is determined according to the system parameter. In step S1003, whether a temperature of the memory storage apparatus reaches the temperature control threshold value is determined. In response to the temperature of the memory storage apparatus reaching the temperature control threshold value, in step S1004, a temperature control mechanism is performed to reduce the temperature of the memory storage apparatus. However, if the temperature of the memory storage apparatus does not reach the temperature control threshold value, then step S1001 may be repeated.

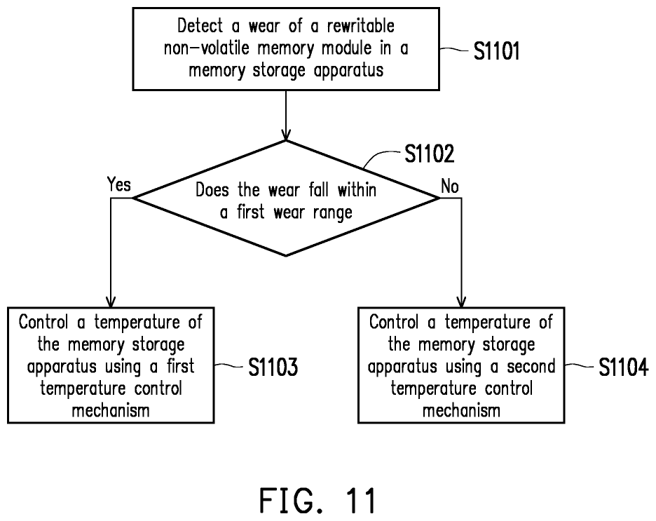

FIG. 11 is a flowchart of a temperature control method according to an exemplary embodiment of the invention. Referring to FIG. 11, in step S1101, wear of a rewritable non-volatile memory module in a memory storage apparatus is detected. In step S1102, whether the wear of the rewritable non-volatile memory module falls within a first wear range is determined. In response to the wear of the rewritable non-volatile memory module falling within the first wear range, in step S1103, a temperature of the memory storage apparatus is controlled using a first temperature control mechanism. Or, in response to the wear of the rewritable non-volatile memory module falling within the second wear range, in step S1104, the temperature of the memory storage apparatus is controlled using a second temperature control mechanism.

However, each step in FIG. 10 and FIG. 11 is as described in detail above, and is not repeated herein. It should be mentioned that, each step in FIG. 10 and FIG. 11 may be implemented as a plurality of program codes or circuits, and the invention is not limited thereto. Moreover, the method of FIG. 10 and FIG. 11 may be used with the above exemplary embodiments, and may also be used alone, and the invention is not limited thereto.

Based on the above, in an exemplary embodiment of the invention, the temperature control threshold value or the adopted temperature control mechanism may be dynamically adjusted according to the wear (or health status) of the rewritable non-volatile memory module. In this way, the optimal balance between the working performance of the memory storage apparatus and the temperature control mechanism is achieved as much as possible.

Although the invention has been described with reference to the above embodiments, it will be apparent to one of ordinary skill in the art that modifications to the described embodiments may be made without departing from the spirit of the disclosure. Accordingly, the scope of the disclosure is defined by the attached claims not by the above detailed descriptions.

What is claimed is:

1. A temperature control method adapted for a memory storage apparatus, wherein the memory storage apparatus comprises a rewritable non-volatile memory module, and the temperature control method comprises:
detecting a system parameter of the memory storage apparatus, wherein the system parameter reflects wear of the rewritable non-volatile memory module;
determining a temperature control threshold value according to the system parameter; and
performing a temperature reducing operation in response to a temperature of the memory storage apparatus reaching the temperature control threshold value to reduce the temperature of the memory storage apparatus.

2. The temperature control method of claim 1, wherein the system parameter comprises a count value reflecting wear of at least one physical unit in the rewritable non-volatile memory module.

3. The temperature control method of claim 2, wherein the count value comprises at least one or a combination of a programming count value, an erase count value, a read count value, and a bit error rate.

4. The temperature control method of claim 1, wherein the step of determining the temperature control threshold value according to the system parameter comprises:
setting the temperature control threshold value to a first value in response to the system parameter being a first parameter value; and
setting the temperature control threshold value to a second value in response to the system parameter being a second parameter value, wherein the first parameter value is different from the second parameter value, and the first value is different from the second value.

5. The temperature control method of claim 1, wherein the step of determining the temperature control threshold value according to the system parameter comprises:
reducing the temperature control threshold value in response to the system parameter reflecting an increase in the wear of the rewritable non-volatile memory module.

6. The temperature control method of claim 1, wherein the temperature control threshold value comprises a first threshold value and a second threshold value, the first threshold value is less than the second threshold value, the first threshold value is configured to trigger a first temperature reducing operation of the memory storage apparatus, the second threshold value is configured to trigger a second temperature reducing operation of the memory storage apparatus, the first temperature reducing operation is different from the second temperature reducing operation, and the step of determining the temperature control threshold value according to the system parameter comprises:
adjusting the first threshold value and the second threshold value simultaneously.

7. The temperature control method of claim 1, further comprising:
reducing at least one of a number of parallel access channels and a system clock of the rewritable non-volatile memory module in the temperature reducing operation.

8. A memory storage apparatus, comprising:
a connection interface unit configured to be coupled to a host system;
a rewritable non-volatile memory module; and
a memory control circuit unit coupled to the connection interface unit and the rewritable non-volatile memory module,
wherein the memory control circuit unit is configured to detect a system parameter of the memory storage apparatus, wherein the system parameter reflects wear of the rewritable non-volatile memory module,
the memory control circuit unit is further configured to determine a temperature control threshold value according to the system parameter, and
the memory control circuit unit is further configured to perform a temperature reducing operation in response to a temperature of the memory storage apparatus reaching the temperature control threshold value to reduce the temperature of the memory storage apparatus.

9. The memory storage apparatus of claim 8, wherein the system parameter comprises a count value reflecting wear of at least one physical unit in the rewritable non-volatile memory module.

10. The memory storage apparatus of claim 9, wherein the count value comprises at least one or a combination of a programming count value, an erase count value, a read count value, and a bit error rate.

11. The memory storage apparatus of claim 8, wherein the operation of determining the temperature control threshold value according to the system parameter comprises:
setting the temperature control threshold value to a first value in response to the system parameter being a first parameter value; and
setting the temperature control threshold value to a second value in response to the system parameter being a second parameter value, wherein the first parameter value is different from the second threshold value, and the first value is different from the second value.

12. The memory storage apparatus of claim 8, wherein the operation of determining the temperature control threshold value according to the system parameter comprises:
reducing the temperature control threshold value in response to the system parameter reflecting an increase in the wear of the rewritable non-volatile memory module.

13. The memory storage apparatus of claim 8, wherein the temperature control threshold value comprises a first threshold value and a second threshold value, the first threshold value is less than the second threshold value, the first threshold value is configured to trigger a first temperature reducing operation of the memory storage apparatus, the second threshold value is configured to trigger a second temperature reducing operation of the memory storage apparatus, the first temperature reducing operation is different from the second temperature reducing operation, and the operation of determining the temperature control threshold value according to the system parameter comprises:
adjusting the first threshold value and the second threshold value simultaneously.

14. The memory storage apparatus of claim 8, wherein the memory control circuit unit is further configured to reduce at least one of a number of parallel access channels and a system clock of the rewritable non-volatile memory module during the temperature reducing operation.

15. A memory control circuit unit configured to control a rewritable non-volatile memory module, the memory control circuit unit comprising:
a host interface configured to be coupled to a host system;
a memory interface configured to be coupled to the rewritable non-volatile memory module; and
a memory management circuit coupled to the host interface and the memory interface,
wherein the memory management circuit is configured to detect a system parameter of the memory storage apparatus, wherein the system parameter reflects wear of the rewritable non-volatile memory module,
the memory management circuit is further configured to determine a temperature control threshold value according to the system parameter, and
the memory management circuit is further configured to perform a temperature reducing operation in response to a temperature of the memory storage apparatus reaching the temperature control threshold value to reduce the temperature of the memory storage apparatus.

16. The memory control circuit unit of claim 15, wherein the system parameter comprises a count value reflecting wear of at least one physical unit in the rewritable non-volatile memory module.

17. The memory control circuit unit of claim 16, wherein the count value comprises at least one or a combination of a programming count value, an erase count value, a read count value, and a bit error rate.

18. The memory control circuit unit of claim 15, wherein the operation of determining the temperature control threshold value according to the system parameter comprises:
setting the temperature control threshold value to a first value in response to the system parameter being a first parameter value; and
setting the temperature control threshold value to a second value in response to the system parameter being a second parameter value, wherein the first parameter value is different from the second parameter value, and the first value is different from the second value.

19. The memory control circuit unit of claim 15, wherein the operation of determining the temperature control threshold value according to the system parameter comprises:
reducing the temperature control threshold value in response to the system parameter reflecting an increase in the wear of the rewritable non-volatile memory module.

20. The memory control circuit unit of claim 15, wherein the temperature control threshold value comprises a first threshold value and a second threshold value, the first threshold value is less than the second threshold value, the first threshold value is configured to trigger a first temperature reducing operation of the memory storage apparatus, the second threshold value is configured to trigger a second temperature reducing operation of the memory storage apparatus, the first temperature reducing operation is different from the second temperature reducing operation, and the operation of determining the temperature control threshold value according to the system parameter comprises:
adjusting the first threshold value and the second threshold value simultaneously.

21. The memory control circuit unit of claim 15, wherein the memory management circuit is further configured to reduce at least one of a number of parallel access channels and a system clock of the rewritable non-volatile memory module during the temperature reducing operation.

22. A memory storage apparatus, comprising:
a connection interface unit configured to be coupled to a host system;
a rewritable non-volatile memory module; and
a memory control circuit unit coupled to the connection interface unit and the rewritable non-volatile memory module,
wherein the memory control circuit unit is configured to detect wear of the rewritable non-volatile memory module,
the memory control circuit unit is further configured to control a temperature of the memory storage apparatus using a first temperature control mechanism in response to the wear falling within a first wear range, and
the memory control circuit unit is further configured to control the temperature of the memory storage apparatus using a second temperature control mechanism in response to the wear falling within a second wear range, wherein the first wear range is different from the second wear range, and the first temperature control mechanism is different from the second temperature control mechanism.

23. The memory storage apparatus of claim 22, wherein a temperature control threshold value used to trigger a temperature reducing operation in the first temperature control mechanism is different from the temperature control threshold value used to trigger the temperature reducing operation in the second temperature control mechanism.
